(19) United States
(12) Patent Application Publication
(10) Pub. No.: US 2025/0079300 A1
(43) Pub. Date: Mar. 6, 2025

(54) MAGNETIC INDUCTORS FOR SEMICONDUCTOR PACKAGING

(71) Applicant: Intel Corporation, Santa Clara, CA (US)

(72) Inventors: Aleksandar ALEKSOV, Chandler, AZ (US); Neelam PRABHU GAUNKAR, Chandler, AZ (US); Henning BRAUNISCH, Phoenix, AZ (US); Wenhao LI, Chandler, AZ (US); Feras EID, Chandler, AZ (US); Georgios C. DOGIAMIS, Chandler, AZ (US)

(21) Appl. No.: 18/240,318

(22) Filed: Aug. 30, 2023

(51) Int. Cl. H01L 23/522; H01F 1/03; H01F 41/16

(52) U.S. Cl. CPC H01L 23/5227; H01F 1/0315; H01F 41/16; H01L 23/49816; H01L 24/16; H01L 2223/6655; H01L 2224/16225; H01L 2924/19042; H01L 2924/30107; H10D 1/20

(57) ABSTRACT

Magnetic inductors for microelectronics packages are provided. Magnetic inductive structures include a magnetic region, a magnetic region base region, and a conductive region that forms a channel within the magnetic region. The magnetic region has a different chemical composition than the base region. Additional structures are provided in which the magnetic region is recessed into a package substrate core. Further inductor structures are provided in which the conductive region includes through-core vias and the conductive region at least partially encircles a portion of a package substrate core. Additionally, methods of manufacture are provided for semiconductor packages that include magnetic inductors.

### FIELD

Descriptions are generally related to packages for semiconductor chips, and more particular descriptions are related to magnetic inductors for semiconductor chip packages.

### BACKGROUND

The semiconductor chips that are central to intelligent devices and systems, such as personal computers, laptops, tablets, phones, servers, and other consumer and industrial products and systems, are packaged so that power can be delivered, data can be input and output, heat can be dissipated, and the chip can be protected from environmental challenges. Packaging of a semiconductor chip is extremely important to optimizing the performance and longevity of the chip.

Packaging semiconductor devices presents a number of challenges and these challenges are amplified as devices become smaller and performance demands increase. Challenges include, for example, unwanted material interactions, precision and scaling requirements, heat management, power delivery requirements, limited failure tolerance, and material and manufacturing costs.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention.

FIGS. 1A-1D show cross-sectional views of exemplary magnetic inductors.

FIGS. 1E-1G provide perspective views for the cross-sectional views of magnetic inductors of FIGS. 1A-1D.

FIGS. 2A-2C show additional examples of magnetic inductors presented in cross-sectional view.

FIG. 3A illustrates a cross-sectional view of an additional magnetic inductor having two different magnetic materials in the inductor structure.

FIG. 3B provides a perspective view for the cross-sectional view of FIG. 3A.

FIG. 4A shows a planar magnetic inductor having more than one magnetic region.

FIGS. 4B-4C provide cross-sectional views of the structure in FIG. 4A.

FIG. 5 shows an expanded section of an exemplary magnetic inductor.

FIGS. 6A-6B show examples of magnetic inductor structures.

FIGS. 7A-7B provide views of an exemplary magnetic inductor.

FIGS. 8A-8B show a section of an example packaging assembly that includes planar magnetic inductors.

FIG. 8C shows the cross-sections for FIGS. 8A-8B.

FIG. 9 shows a section of an additional example packaging assembly that includes magnetic inductors.

FIG. 10 provides a flow diagram of an example of a process for manufacturing a planar magnetic inductor.

FIG. 11 shows a process flow for manufacturing an additional example of a planar magnetic inductor.

FIG. 12 provides a diagram of a method for manufacturing a magnetic inductor on a packaging substrate.

FIG. 13 provides a method for manufacturing magnetic inductors.

FIG. 14 is a block diagram of a system in which exemplary magnetic inductors are employed.

Descriptions of certain details and implementations follow, including non-limiting descriptions of the figures, which depict non-limiting examples and implementations.

### DETAILED DESCRIPTION

References to one or more examples are to be understood as describing a particular feature, structure, or characteristic included in at least one implementation of the invention. The phrase “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following after some other event or events. Other sequences of operations can also be performed according to alternative embodiments. Furthermore, additional operations may be added or removed depending on the particular application.

Disjunctive language such as the phrase “at least one of X, Y, or Z,” is used in general to present that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine and/or physical operations. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions. The physical operations can be performed by, for example, semiconductor process equipment.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine readable storage medium can cause a machine to perform the functions or operations described, and includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, or semiconductor chip are used interchangeably and refer to a semiconductor device comprising integrated circuits.

The terms “package,” “packaging,” “IC package,” or “chip package,” “microelectronics package,” or “semiconductor chip package” are interchangeable and generally refer to an enclosed carrier of one or more dies, in which the dies are attached to a packaging substrate and encapsulated. The packaging substrate provides electrical interconnects between the die(s) and other dies and/or a motherboard or other printed circuit board for I/O (input/output) communication and power delivery. A package with multiple dies can be a system in a package for example. A package with multiple chips can also include an interposer that can be a silicon interposer that allows attachment of multiple chips.

A packaging substrate generally includes dielectric layers or structures having conductive structures on and/or embedded within the dielectric layers or structures. Other structures or devices are also possible within a packaging substrate. Semiconductor packaging substrates can have cores or be coreless.

A “core” or “package core” generally refers to a layer usually embedded within a packaging substrate. The core can provide structure or stiffness to a package. A core is an optional feature of a packaging substrate. The core can be a dielectric organic or inorganic material and may have conductive vias extending through the layer. A package core can, for example, comprise glass (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy).

In further examples of a package core, the core can comprise a solid amorphous glass such as, for example, aluminosilicate, borosilicate, alumino-borosilicate, silica, and fused silica, that optionally additionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples the glass can comprise silicon and oxygen, as well as any one or more of: aluminum, boron, magnesium, calcium, barium, tin, sodium, potassium, strontium, phosphorus, zirconium, lithium, titanium, and/or zinc. In some examples, the glass comprises at least 23% silicon, at least 26% oxygen, and at least 5% aluminum by weight.

Power delivery networks for semiconductor chips can include voltage regulators (VRs) that are voltage regulating circuits. In one example, VRs are integrated into semiconductor chips and comprise part of the power delivery network. Integrated voltage regulators in some instances are referred to as fully integrated voltage regulators (FIVR). Voltage regulation systems such as FIVR can be employed in chips that are used in data centers among other places. Inductors located in semiconductor chip packages are important parts of a power delivery network comprising FIVR.

Voltage regulators that can operate at higher voltages can provide advantages. For example, if a VR can operate at a voltage that is 5 V or higher, a significant decrease in power delivery (PD) losses might be achieved. In a simplified calculation that provides a useful approximation of a more complex situation, power (P) equals current (I) times voltage (V) (P=IV), therefore I=P/V. Power losses in the PD path can be approximated as ohmic losses. Ohmic losses can be calculated approximately as I²R where R is the resistance of the system. Therefore, at a constant power, a voltage increase reduces the current needed, and therefore reduces the ohmic losses. In this example, a voltage increase of 2× voltage leads to a 2× decrease in current and a 4× decrease in PD losses. Inductor structures that can handle higher voltages are an important part of decreasing power losses in the PD path.

Magnetic inductor structures that are useful for semiconductor packaging applications are provided. Magnetic inductors are useful, for example, in a power delivery network. Magnetic inductor structures as described herein can also provide manufacturing advantages and allow scaling to increasingly small-sized structures. Multiple magnetic inductors can be used in semiconductor chip packages and some or all of them can be connected in series or connected in parallel.

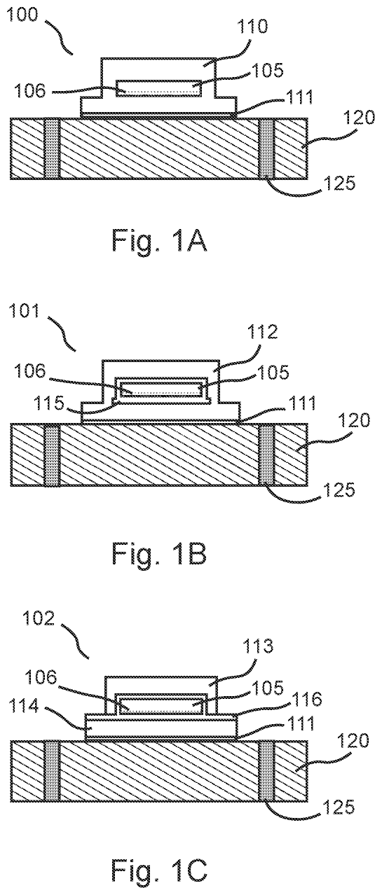

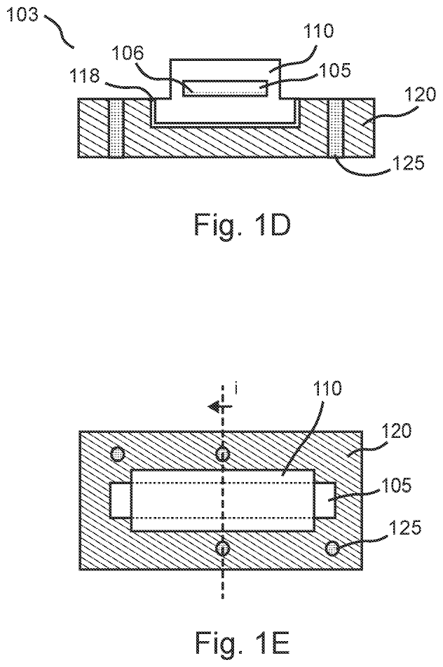

FIGS. 1A-1D show examples of planar magnetic inductors that are in packaging substrates. FIG. 1E shows a rotated view of a planar magnetic inductor structure that is located in a packaging substrate. A dashed line and arrow labeled “i” in FIG. 1E illustrate the direction and cross-sectional line for the views shown in FIGS. 1A-1B. FIGS. 1F-1G provide rotated views for the planar magnetic inductor structures shown in FIGS. 1C-1D, respectively.

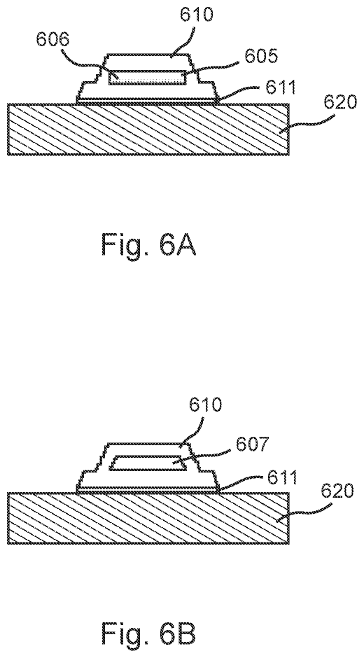

In FIG. 1A an example inductor structure 100 has a planar magnetic inductor that includes a conductive region 105 and a magnetic region 110. The conductive region 105 comprises a conductive material, such as a metal. An optional seed layer 106 is between the conductive region 105 and the magnetic region 110. The seed layer 106 can be created during a conductor deposition process, for example seed layers can be used for metal plating processes, such as for copper plating processes. In the example of inductor structure 100, the magnetic material in region 110 is sufficiently resistive and a non-magnetic dielectric layer has not been used between the conductive region 105 and the magnetic region 110. In some examples, sufficiently high resistive magnetic materials exhibit specific resistivity of 10³ Ohm*m to up to 10²³ Ohm*m. Cold spray deposition techniques allow the creation of magnetic regions and structures that are useful for planar magnetic inductors. Cold spray deposition techniques create magnetic regions comprised of homogeneous magnetic material. A magnetic region 110 that has been created by a cold spray deposition process has a base region 111. Base region 111 can comprise two or more layers such as a cold spray buffer metal layer and an adhesion layer. FIG. 5 provides additional description of the base region 111. The planar magnetic inductor is shown on a package substrate core 120 and could also alternatively be embedded within a packaging substrate (not shown) or be separated from the core 120 by one or more layers of material (not shown). In the illustration in FIG. 1A, the conductive through-core vias 125 are optional, and may either be present or not and may be present in the core 120 (or substrate) but in a different configuration and/or number.

FIG. 1B illustrates a further example of a planar magnetic inductor structure. Magnetic inductor structure 101 has a planar magnetic inductor which includes conductive region 105, magnetic region 112, and non-magnetic dielectric layer 115. The conductive region 105 comprises a conductor, such as a metal. An optional seed layer 106 for the conductive region 105 is shown. Non-magnetic dielectric layer 115 is between the conductive region 105 and the magnetic region 112. In the example of FIG. 1B, the magnetic material of magnetic region 112 may be a lower resistance magnetic material or a high resistance material. In some examples, lower resistance (insulating) magnetic materials have resistivities typically 10⁴ Ohm*m to 10⁶ Ohm*m. A magnetic region 112 that has been created by a cold spray deposition process has a base region 111. Base region 111 can comprise two or more layers such as a cold spray buffer metal layer and an adhesion layer. FIG. 5 provides additional description of the base region 111. The planar magnetic inductor in FIG. 1B is on a package substrate core 120, however it can also be embedded within a packaging substrate (not shown) or separated from the core 120 by one or more layers of material (not shown). In the illustration in FIG. 1B, the conductive through-core vias 125 are optional, and may either be present or not and may be present in the core 120 but in a different number, configuration, and/or number.

FIG. 1C provides another example of a planar magnetic inductor useful for example, for packaging semiconductor devices. In FIG. 1C, magnetic inductor structure 102 includes a planar magnetic inductor that has conductive region 105, magnetic regions 113 and 114, and non-magnetic dielectric layer 116. The conductive region 105 comprises a conductor, such as a metal. An optional seed layer 106 for the conductive region 105 is shown. Non-magnetic dielectric layer 116 is between the conductive region 105 and the magnetic region 113 and between the conductive region 105 and the magnetic region 114. Magnetic regions 113 and 114 can be the same or different magnetic material. Because a non-magnetic dielectric layer 116 separates the magnetic regions 113 and 114 from the conductive region 105, magnetic materials exhibiting either high resistances or lower resistances can be used. In some examples the resistance of the magnetic material is greater than 10³ Ohm*m. A magnetic region 113 and/or 114 that has been created by a cold spray deposition process may include a base region 111. In FIG. 1C, the planar magnetic inductor is on a package substrate core 120 or alternatively embedded within a packaging substrate (not shown) or separated from the core by one or more layers (not shown). In the illustration in FIG. 1C, the conductive through-core vias 125 are optional, and may either be present or not and may be present in the core 120 but in a different configuration and/or number.

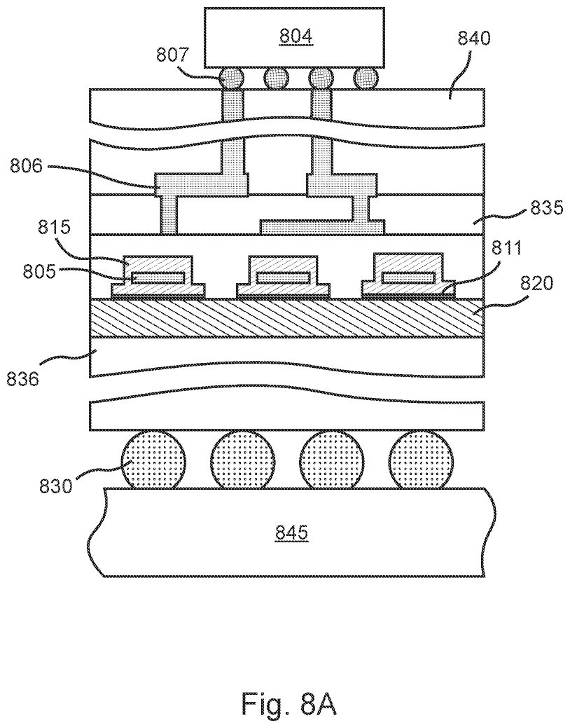

In examples of magnetic inductors employed herein, the thickness of the non-magnetic dielectric layers (for example, 115 and 116 of FIGS. 1B and 1C, respectively, and any non-magnetic dielectric layers employed in FIGS. 7A-7B, 8A-8C, and 9) can optionally be determined according to the following equation:

$$d ≫ \frac{2 π \cdot {f}_{s} \cdot {ρ}_{m} \cdot {ε}_{d} \cdot {ε}_{0} \cdot {ℓ}_{e d d y}^{2}}{{δ}_{s m}} \qquad ( 1 )$$

where in equation (1), d represents the minimum thickness of the dielectric layer. Further, in equation (1), fₛ is the switching frequency, ρₘ is the resistivity of the magnetic material, ε_{d} is the relative dielectric number of the dielectric material, co is the permittivity of free space (approximately 8.85×10⁻¹² F/m), [symbol] _{eddy} is the length of the eddy current path, and δₛₘ is the skin depth of the magnetic material at the switching frequency (fₛ) and δₛₘ=\sqrt{ρₘ/(πμᵣμ₀fₛ)}, where μᵣ is the relative magnetic permeability of the magnetic material and μ₀ is the magnetic permeability of free space (μ₀=4π×10⁻⁷ H/m). In a sample calculation, the eddy path length ( [symbol] _{eddy}) is chosen to be 1 mm, the switching frequency is 50 MHZ, the conductive region is Cu, the magnetic material is CZT (CoZrTa), and the dielectric layer is SiO₂ (for which ε_{d} is about 4). CZT has a μᵣ of about 650 and ρₘ of about 100 μΩcm. Using these values, the right side of equation (1) is calculated to be about 4 nm. Since according to equation (1), the minimum thickness, d, is much greater than this calculated number, choosing a value such as 10×-50× greater, d becomes about 40 nm-200 nm. In some additional examples of 1 mm long inductors with various different magnetic regions that have an insulating layer between the magnetic region and a Cu conductive region, the thickness of the insulating layer (d) is between 25 nm and 500 nm.

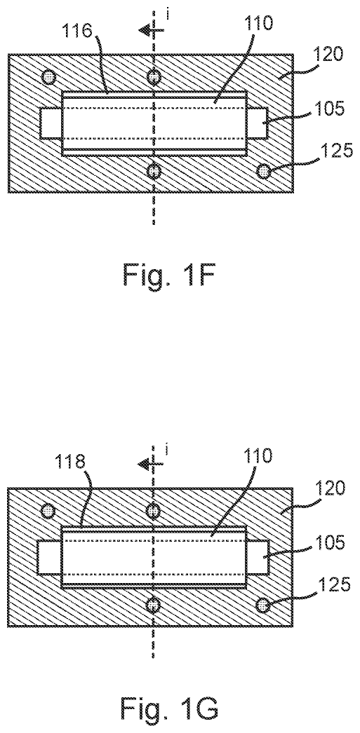

FIG. 1D illustrates a further example of a magnetic inductor structure. In FIG. 1D, a magnetic inductor structure 103 has a planar magnetic inductor that is partially recessed within a package substrate core 120. The planar magnetic inductor includes conductive region 105 and magnetic region 110. The conductive region 105 comprises a conductor, such as a metal. An optional seed layer 106 for the conductive region 105 is shown. A magnetic region 110 that has been created by a cold spray deposition process has a base region 118. Base region 118 can comprise two or more layers such as a cold spray buffer metal layer and an adhesion layer. FIG. 5 provides additional description of the base region 118. In FIG. 1D, the planar magnetic inductor is recessed into a package substrate core 120. In the illustration in FIG. 1D, the conductive through-core vias 125 are optional, and may either be present or not and may be present in the package substrate core 120 but in a different number, configuration, and/or number. Although in FIG. 1D a planar magnetic inductor similar to that shown in FIG. 1A is shown partially recessed in a package substrate core 120, any of the planar magnetic inductors of FIGS. 1B-1C and FIGS. 2A-2C could be similarly partially recessed within a package substrate core 120.

FIG. 1E provides an exemplary top view (or bottom view, depending on device orientation) of the cross-sectional views of FIGS. 1A-1B. The cross-section is taken along the dashed line labeled “i.” An arrow in the dashed line labeled “i” indicates the direction of view. The numbering is provided with respect to FIG. 1A and corresponding numbers for FIG. 1B provided subsequently in “( )” In FIG. 1E, a planar magnetic inductor includes conductive region 105 and magnetic region 110 (112). In FIG. 1E, the planar magnetic inductor is on a package substrate core 120 or alternatively embedded in a package substrate (not shown). FIG. 1F additionally illustrates the non-magnetic dielectric layer 116 of FIG. 1C. FIG. 1G also illustrates the base region 118 of FIG. 1D. In the illustrations in FIG. 1E-1G, the conductive through-core vias 125 are optional, and may either be present or not and may be present in the package substrate core 120 but in a different number, configuration, and/or number.

FIGS. 2A-2C provide additional examples of planar magnetic inductors. In these examples, the planar magnetic inductor similar to that of FIG. 1A has been used for illustration purposes, but any of the inductors of FIGS. 1A-1D, FIG. 3A-3B, and FIG. 4A-4C could be also used. In FIG. 2A planar magnetic inductors have been created on both sides of a package substrate core 220. Structure 200 has planar magnetic inductors that include a conductive region 205 and a magnetic region 210. The conductive region 205 comprises a conductor, such as a metal. An optional seed layer 206 for the conductive region 205 is shown. The conductive region 205 is comprised, for example, of Cu. A magnetic region 210 that has been created by a cold spray deposition process can have a base region 211. Base region 211 can comprise two or more layers such as a cold spray buffer metal layer and an adhesion layer. FIG. 5 provides additional description of the base region 211. In FIG. 2A, the planar magnetic inductors are on opposite sides of a package substrate core 220 or alternatively embedded in a packaging substrate (not shown) in a similar configuration. Additionally, the planar magnetic inductors could be separated from the core 220 by one or more layers of material (not shown).

FIG. 2B provides a further example of a planar magnetic inductor structure. In FIG. 2B, an inductor structure 201 has an inductor that includes two conductive regions 205 that share one magnetic region 212. An insulating region 218 that is not magnetic is between the conductive regions 205. Although this example shows two conductive regions, other numbers of conductive regions 205 sharing a single magnetic region 212 and having non-magnetic insulating regions 218 between are possible. For example, 3, 4, 5, or more conductive regions 205 could share a single magnetic region 212. The conductive region 205 comprises a conductor and an optional seed layer 206. A magnetic region 212 that has been created by a cold spray deposition process has a base region 211. In FIG. 2B, the planar magnetic inductor is illustrated on a package substrate core 220 but could also be within a packaging substrate (not shown). In an additional example, the planar magnetic inductors are separated from the core 220 by one or more layers of material (not shown).

FIG. 2C illustrates another example of a planar magnetic inductor structure. In FIG. 2C, an inductor structure 202 has an inductor that includes two conductive regions 205 that share one magnetic region 213. Although this example shows two conductive regions 205, other numbers of conductive regions 205 sharing a single magnetic region 213 are possible. For example, 3, 4, 5, or more conductive regions 205 could share a single magnetic region 213. The conductive region 205 comprises a conductor and an optional seed layer 206. A magnetic region 213 that has been created by a cold spray deposition process has a base region 211. In FIG. 2B, the planar magnetic inductor is illustrated on a package substrate core 220 but could also be within a packaging substrate (not shown). In an additional example, the planar magnetic inductor is separated from the core 220 by one or more layers of material (not shown).

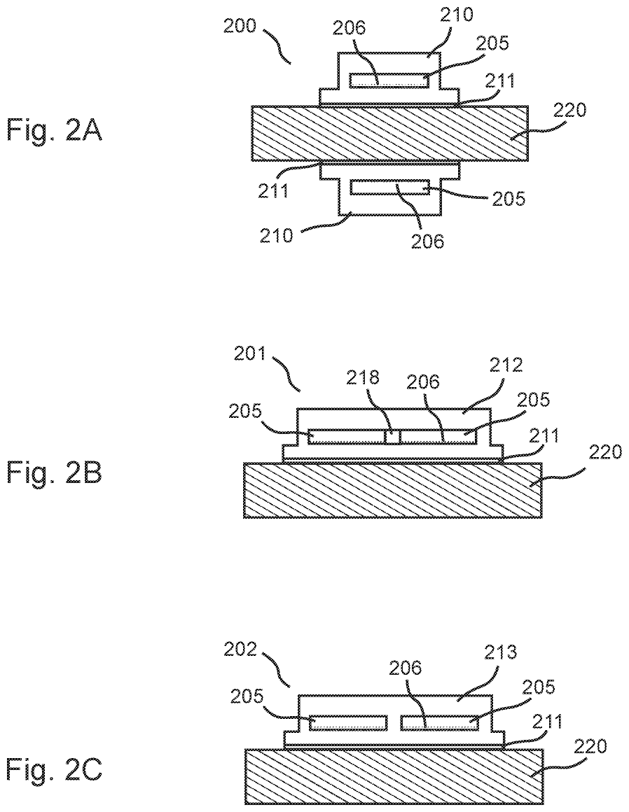

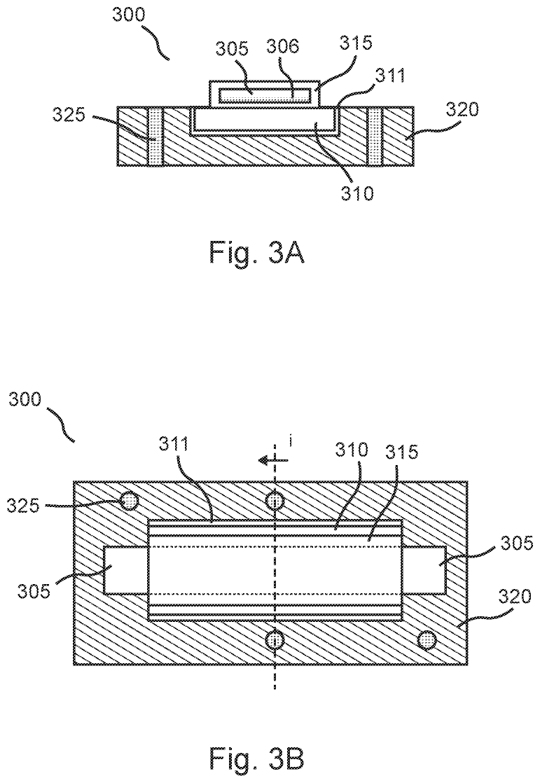

FIG. 3A shows another example of a planar magnetic inductor. In FIG. 3A, the inductor structure 300 has a magnetic inductor that includes a conductive region 305 and a first magnetic region 310 and a second magnetic region 315. The magnetic regions 310 and 315 are comprised of different magnetic materials. In this example, the magnetic region 310 is recessed within the packaging substrate 320. In other examples, the magnetic inductor 310 could be partially recessed or not recessed, such as in FIGS. 1A-1C and could comprise more than one conductive region, such as in FIGS. 2B-2C, or could be on both sides of a packaging substrate such as in FIG. 2A. The conductive region 305 comprises a conductor and an optional seed layer 306. A magnetic region 310 that has been created by a cold spray deposition process has a base region 311. Base region 311 can comprise two or more layers such as a cold spray buffer metal layer and an adhesion layer. FIG. 5 provides additional description of the base region 311. The conductive through-substrate vias 325 are optional, and may either be present or not and may be present in the substrate 320 but in a different configuration and/or number. FIG. 3B provides a top (or bottom depending on orientation) view of the inductor structure 300 of FIG. 3A. The dashed line labeled “i” shows the cross-sectional plane for FIG. 3A and the arrow in the dashed line shows the direction of view. The conductive through-substrate vias 325 shown in FIG. 3B are also optional, and may either be present or not and may be present in the substrate 320 but in a different configuration and/or number.

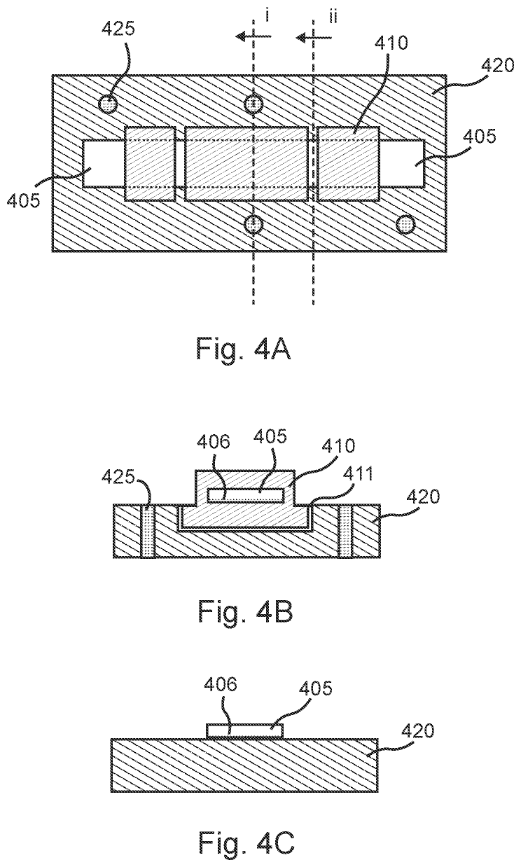

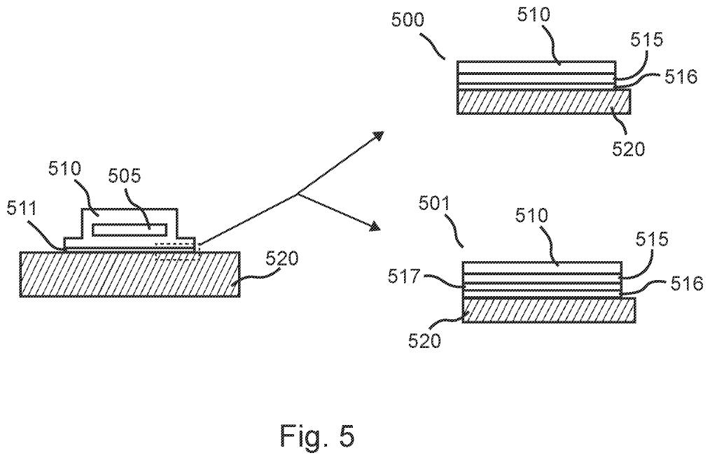

FIG. 4A provides a further exemplary configuration of a planar magnetic inductor. In this exemplary planar inductor structure, there is more than one magnetic region 410 along the path of the conductive region 405. Dashed lines “i” and “ii” show the cross-sectional cut for FIGS. 4B and 4C respectively and arrows show the direction of view. The conductive through-substrate vias 425 shown in FIGS. 4A and 4B are also optional, and may either be present or not and may be present in the core 420 but in a different configuration and/or number. In FIG. 4B, the magnetic region 410 is shown as recessed into the core 420. Other configurations of the planar magnetic inductor are also possible, such as those shown in FIGS. 1A-1C. A magnetic region 410 that has been created by a cold spray deposition process can have a base region 411. Base region 411 can comprise two or more layers such as a cold spray buffer metal layer and an adhesion layer. FIG. 5 provides additional description of the base region 411. The conductive region 405 comprises a conductor and an optional seed layer 406. In FIG. 4C, the magnetic region 410 is not present.

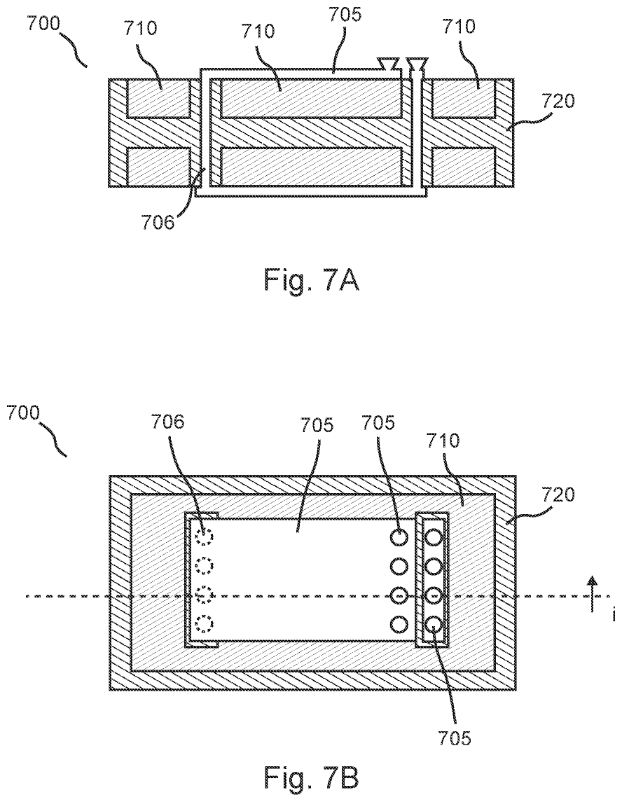

FIG. 5 provides additional detail about the base region for a magnetic region that has been created by a cold spray deposition process. The magnetic region base region 511 discussed with respect to FIG. 5 could be any of the base regions 111, 118, 211, 311, 411, or 611 of the previous and next examples (FIGS. 6A-6B and FIGS. 7A-7B). In examples provided herein the magnetic region can be created by a cold spray deposition process. Cold spray is a process that allows a material to be deposited on a surface and involves accelerating solid particles of the material toward the deposition surface. In FIG. 5, a magnetic inductor has magnetic region 510, conductive region 505 and is on a packaging substrate 520. The magnetic region 510 has a base region 511. The magnetic base region 511 is frequently implemented when a cold spray deposition process has been used. The base region 511 is shown expanded in structures 500 and 501. Cut away and expanded structure 500 shows the magnetic region 510, buffer metal layer 515, and adhesion layer 516. In this example, the base region 511 is on a packaging substrate 520. Structure 501 provides a further example of a base region 511. In expanded structure 501, the buffer region 511 includes an adhesion layer 516, a seed layer 517, and a buffer metal layer 515. If the cold spray buffer metal layer 515 has been sputtered, the seed layer 517 may not be used. In an example where the buffer metal layer has been plated, seed layer 517 is present in the magnetic base region 511. Structure 501 also includes a partial magnetic region 510 and packaging substrate 520. The buffer metal layer 515 can be a metal such as, for example, Cu, Au, Ru, Al, or a combination thereof. The adhesion layer 516 can be for example, Ti, Ta, SnO, ZnO, or a combination of two or more of these materials. The seed layer 517 can be, for example, Cu or Ru or another metal or combination of metals that is used as a seed layer for plating the buffer metal layer 515. In some examples, the thickness of the buffer metal layer 515 can be 90-110 nm for a layer of Al, and the thickness can be 200 nm-2 μm for a layer of Cu and Al.

FIGS. 6A and 6B provide illustrations of an example of a planar magnetic inductor that has been fabricated by a cold spray process. For clarity, structures of inductors have been shown herein with clean side edges in most figures presented. However, it should be noted that the structures under magnification may have more irregular shapes. For example, FIG. 6A shows a possible shape of a planar magnetic inductor that has been fabricated by a cold spray deposition process. In FIG. 6A, the magnetic region 610 has non-uniform side walls. The planar magnetic inductor also includes conductive region 605, seed layer 606, and a base region 611. The magnetic inductor is on a substrate 620. FIG. 6B both the magnetic region 610 and the conductive region 607 have non-uniform sidewalls. The conductive region 607 has also been fabricated by a cold spray deposition process. Other parts of the planar magnetic inductor include a base region 611 for the magnetic region 610. The magnetic inductor is also on a substrate 620 in FIG. 6B.

FIGS. 7A and 7B show views of an additional example of a magnetic inductor. The cross-sectional plane for the cross-section shown FIG. 7A is shown in FIG. 7B as a dashed line and labeled “i.” In FIG. 7A, a magnetic inductor structure 700, includes magnetic region 710 and conductive region 705. The magnetic region 710 is recessed in the package substrate core 720 and the conductive region 705 includes through-core vias 706. The conductive region 705 can include a seed layer (not shown). Additionally, there can optionally be an insulating layer (not shown) between the magnetic region 710 and the conductive region 705 where they might otherwise contact each other. The magnetic regions additionally include a base region (not shown, but as described, for example in FIG. 5). FIG. 7B provides a top (or bottom view depending on perspective) of the magnetic inductor structure 700. The magnetic inductor includes magnetic regions 710 that are recessed into core 720. These magnetic inductors can be partial single loop (or turn) inductors or multi-loop inductors. In FIG. 7B, there is a single-loop inductor shown utilizing four through-core vias in parallel, however other numbers are possible. The vias in parallel could also be combined into a line via or trench via, provided the substrate core supports these types of non-circular through-core vias. The magnetic material in FIGS. 7A and 7B is arranged as a double-E magnetic core, with two such magnetic cores stacked on top of each other utilizing recesses in the front and back side of the substrate core, respectively. Here “double-E” refers to a rectangular shape with two rectangular holes through it, somewhat like a sideways figure eight.

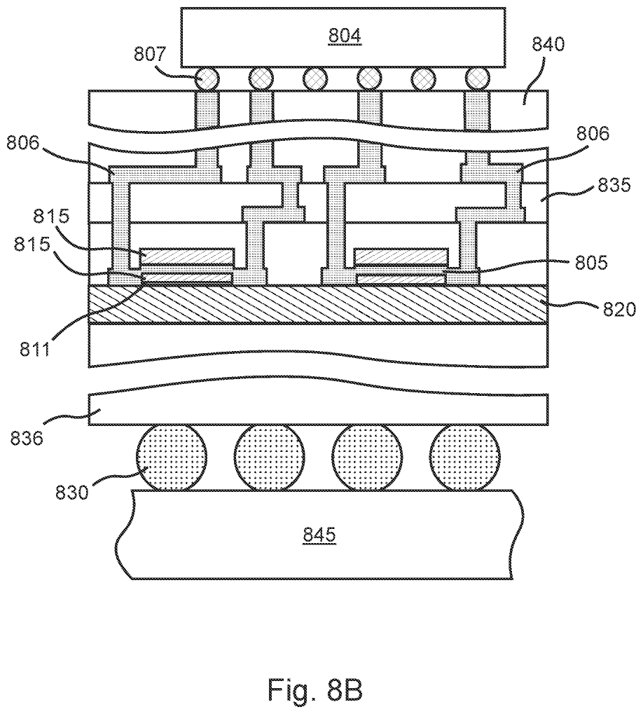

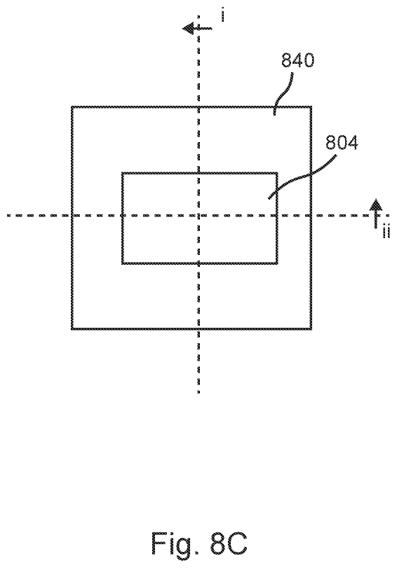

FIGS. 8A-8B show an example section of a packaging structure having planar magnetic inductors. FIG. 8C illustrates the cross-sectional planes (dashed lines) for cross-sectional views provided in FIGS. 8A-8B. The plane labeled “i” represents FIG. 8A and the plane labeled “ii” represents FIG. 8B. As can be seen, the cross-sections are at 90 degrees to one another. The packaging structures of FIGS. 8A-8B include a semiconductor chip 804, however, the structures shown do not include all the packaging layers and features that might be included for the semiconductor chip 804 package and features are not necessary illustrated relatively to scale. For example, the end layer 840 shown in FIGS. 8A-8C would be unlikely to be the end layer of a packaged semiconductor chip in service as most packages, for example, further encapsulate a semiconductor chip 804. Further, a packaging structure could include additional semiconductor chips (not shown). In the package structures shown in FIGS. 8A-8B, the chip 804 is electrically coupled to the package through chip connectors 807. Chip connectors 807 could also be pins, rods, bumps, or types of electrically conductive features used to join the chip 804 to a packaging substrate and provide power and communication. For clarity, only part of a complete package is shown and layers, buildup layers, electrical interconnections, devices, and features, for example, have been omitted. In this example, magnetic inductors that include a conductive region 805 and a magnetic region 815 are on packaging substrate 820. The conductive region 805, can be for example, Cu. The magnetic region 815 can include a base region 811. A planar magnetic inductor similar to the one shown in FIG. 1A has been used in this example, however, the magnetic inductors shown in FIGS. 1B-1E, FIGS. 2A-2C, FIGS. 3A-3B, FIGS. 4A-4C, FIG. 5, and FIG. 6A-6B could also be used. Packaging structure has board-side connectors 830 that are electrically and communicatively attached to contacts on a board 845 (which could be a motherboard, mainboard, main circuit board, printed circuit board, circuit board, system board, or logic board). The board-side connectors 830 can be solder balls, pins, pads, or other types of electrical contacts. The board-side connectors 830 can be a ball grid array (BGA), land grid array (LGA) or pin grid array (PGA) or for use with a LGA or PGA or for coupling to a socket feature of a motherboard. The packaging structure also contains other layers 835 and 836 (which are, for example, buildup layers) and conducting interconnects 806 in the layers 835 and 836 (which are not all pictured). The conducting interconnects 806 comprise in part vias through the layers 835 (and 836 not shown). The package substrate can have additional buildup layers, conducting interconnects, conducting vias, devices, and features that are not shown. The planar magnetic inductors can be part of a power delivery system for chip 804.

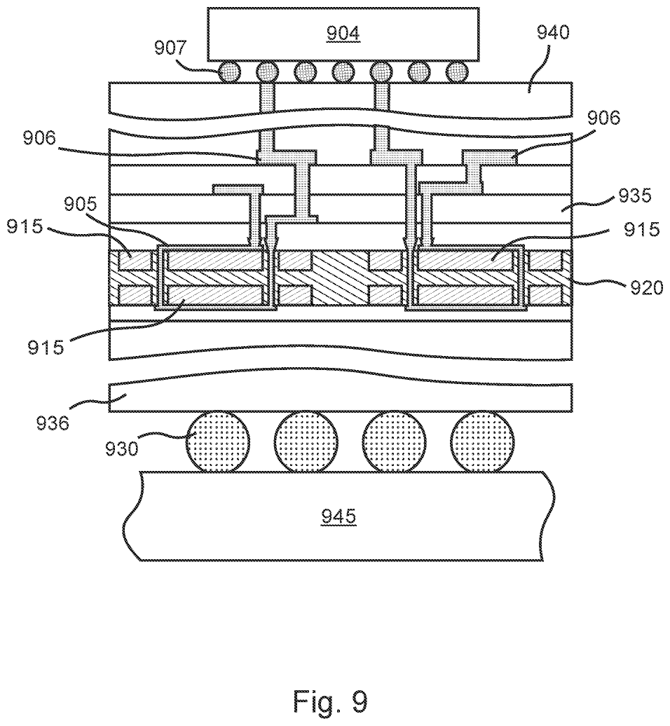

FIG. 9 provides an additional example of a section of a semiconductor chip package having inductors. The packaging structure of FIG. 9 includes a semiconductor chip 904, however, the structure shown does not include all the packaging layers and features that might be in a package structure for semiconductor chip 904 and features are not necessary illustrated relatively to scale. For example, the end layer 940 would be unlikely to be the end layer of a packaged semiconductor chip as most packages, for example, further encapsulate a semiconductor chip 904. Further, a packaging structure could include additional semiconductor chips (not shown). In the package structure of FIG. 9, the chip 904 is electrically coupled to the package through chip connectors 907. Chip connectors 907 could also be pins, rods, bumps, or types of electrically conductive features used to join the chip 907 to a packaging substrate and provide power delivery and communication to the chip. For clarity, only part of a complete package is shown and layers, buildup layers, electrical interconnections, devices, and features, for example, have been omitted. Magnetic inductors that include a conductive region 905 and a magnetic region 915 are integrated into package substrate core 920. The magnetic regions 915 are recessed within package substrate core 920 and the conductive regions 905 of the magnetic inductor include through substrate vias. The magnetic region 915 can include a base region (not shown). A magnetic inductor shown in FIGS. 7A-7B has been used in this example. The packaging structure has board-side connectors 930 that are electrically and communicatively attached to contacts on a board or motherboard 945 (mainboard, main circuit board, printed circuit board, circuit board, system board, or logic board). The board-side connectors 930 can be solder balls, pins, pads, or other types of electrical contacts. The board-side connectors 930 can be a ball grid array (BGA), land grid array (LGA) or pin grid array (PGA) or for use with a LGA or PGA or for coupling to a socket feature of a motherboard. The packaging structure also contains other layers 935 and layers 936 (that can be buildup layers) and conducting interconnects 906. The layers 935 and 936 can have additional electrical interconnects and features that are not shown. The conducting interconnects 906 comprise in part vias through the layers 935 (and 936 not shown). The planar magnetic inductors can be part of a power delivery system for chip 904.

Motherboards (or mainboard, main circuit board, printed circuit board, circuit board, system board, or logic board) such as those shown in FIGS. 8A-8C and FIG. 9 provide electrical contacts, i.e., power delivery and communication routes. Numerous electronic components can be housed on a motherboard, including processors (Central Processing Units (CPUs), graphics processing units (GPUs), digital signal processors (DSPs), coprocessors, network processors, etc.), accelerators, memory controllers, application-specific integrated circuits (ASICs), interface controllers, chipsets, systems in a chip, dual in-line memory modules (DIMMs) or RAM, non-volatile memory, power input and delivery connections, clock generators, BIOS (basic input/output system) chips, and interfaces and connectors peripherals and memory storage devices. The motherboard may contain slots or other types of connectors that accept DIMM or RAM cards, graphics cards or expansion cards. Additional connectors include, for example, Serial Advanced Technology Attachment (SATA) ports, and Peripheral Component Interconnect (PCI) and PCIe (PCI express) slots. Connectors for I/O devices such as peripherals can include, for example, high-definition multimedia interfaces (HDMI), Institute of Electrical and Electronics Engineers (IEEE) standard 1394 bus (Firewire) and universal serial bus (USB) connection receivers for mice, keyboards, storage devices, displays, and cameras, among other devices.

Magnetic inductors can be used in packaging for semiconductor chips. For example, the semiconductor chip, such as those shown in FIGS. 8A-8C and FIG. 9 could be a CPU, a GPU, a DSP, a coprocessor, microprocessor, a network processor, an accelerator, a memory controller, an ASIC, a system in a chip, Infrastructure Processing Unit (IPU), data processing unit (DPU), GPGPU (general-purpose computing on graphics), or a combination of processors or microprocessors. The package could include multiple semiconductor chips. A CPU or other processor or combination, could be multiple smaller chips rather than one single chip.

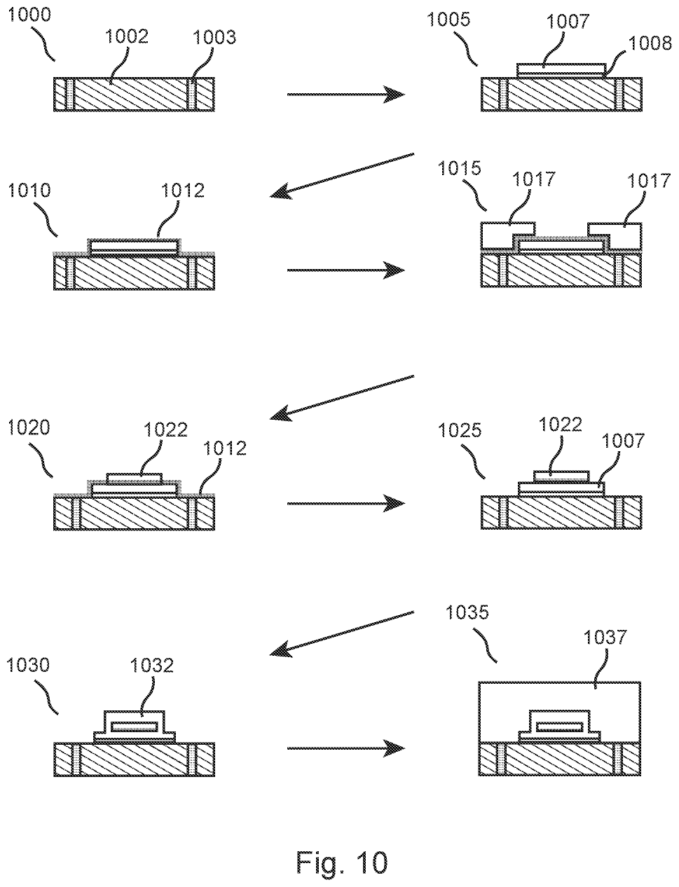

A manufacturing process for a planar magnetic inductor manufactured on one side of a package substrate core is provided in FIG. 10. Other methods for creating planar magnetic inductors are possible. In FIG. 10, structure 1000 shows a package substrate core 1002 having two through-core vias 1003 that have a conductive fill. The conductive fill can be a metal such as Cu or Al or other conductive material. The through-core vias 1003 are optional and may not be present, or be present in different locations and/or numbers. To create structure 1005, 1) a base region 1008 was created, 2) a templated cold spray deposition of magnetic material was performed, 3) the base layer was etched using the magnetic material as a mask, and 4) the deposited magnetic material was mechanically planarized to reduce roughness from the cold spray process. Templates for cold spray deposition processes are mask structures that can be, for example, machined metal plates (e.g., stainless steel) or membranes. The base region 1008 for the magnetic region 1007 can be a plurality of layers, such as for example, those described with respect to FIG. 5 and including an adhesion layer and a buffer metal layer. The base region 1008 can also optionally include a seed layer. The several layers of base region 1008 were individually deposited. A seed layer 1012 for conductive region plating was then deposited to create structure 1010. The seed layer 1012 can comprise, for example, Ti/Cu, Ta/Cu, TiN/Cu, TaN/Cu, Ti/Ru, Ta/Ru (which can be bi-layers), Ru, and/or Cu. A mask layer 1017 comprising, for example, a photoresist, was deposited and lithographically etched to create structure 1015 and define the area for creating the conductive region. The conductive region 1022 of structure 1020 was created by plating a metal and removing the mask region 1017. The conductive region 1022 can comprise Cu. The seed layer 1012 was etched yielding structure 1025 having a conductive region 1022 on a magnetic region 1007. A templated deposition of magnetic material was performed to create structure 1030 having magnetic region 1032. The dielectric region 1037 of structure 1035 was created through a buildup deposition process or molding process.

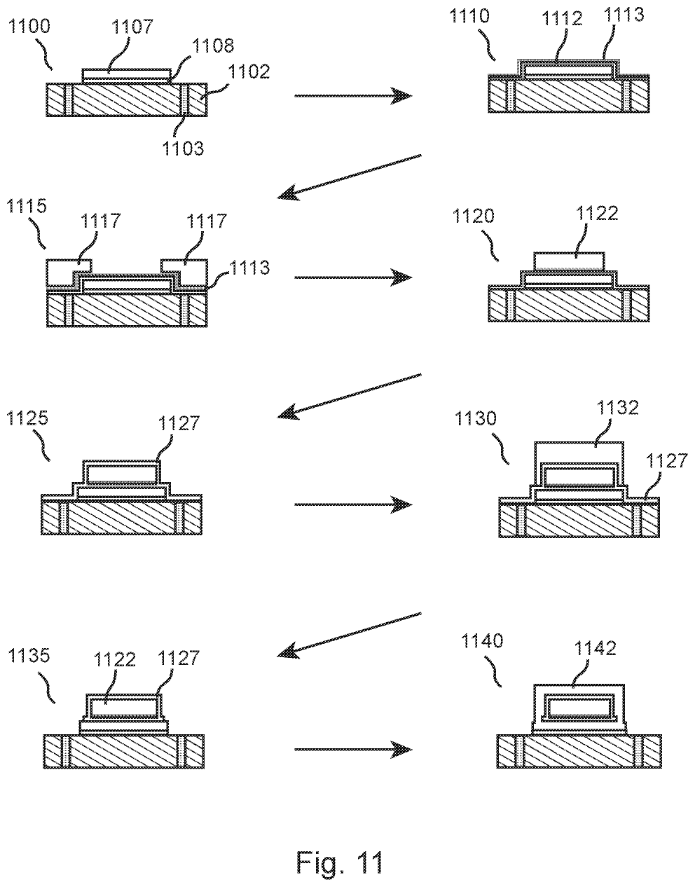

FIG. 11 provides manufacturing process for a planar magnetic inductor having an insulating region between the conductive region and the magnetic region. In FIG. 11, structure 1100 has been manufactured similarly to structure 1005 of FIG. 10. In FIG. 11, package substrate core 1102 has optional through substrate vias 1103 and a magnetic region 1107. The magnetic region 1107 has a base region 1108. To form structure 1110, an insulating layer 1112 was deposited and then a metal seed layer 1113 was deposited on the insulating layer 1112. The metal seed layer 1113 is for example, a copper seed layer for plating copper. In structure 1115, a mask layer 1117 comprising for example, a photoresist, was deposited and lithographically etched to define the area for creating the conductive region. In structure 1120, the conductive region 1122 was created by plating a metal. Additionally, the mask layer 1117 was removed and the seed layer was etched to create structure 1120. The conductive region 1122 can comprise Cu. Insulator was deposited to create structure 1125 having insulating layer 1127. A photoresist was deposited and etched to create structure 1130 having photoresist region 1132. Photoresist region 1132 was used to mask the region where insulator is desired and to etch away insulator 1127 from the unmasked regions, creating structure 1135 upon removal of the photoresist region 1132. Structure 1135 has a conductive region 1122 with insulating material 1127 on four sides. Structure 1140 was created by templated deposition of additional magnetic material to create magnetic region 1142.

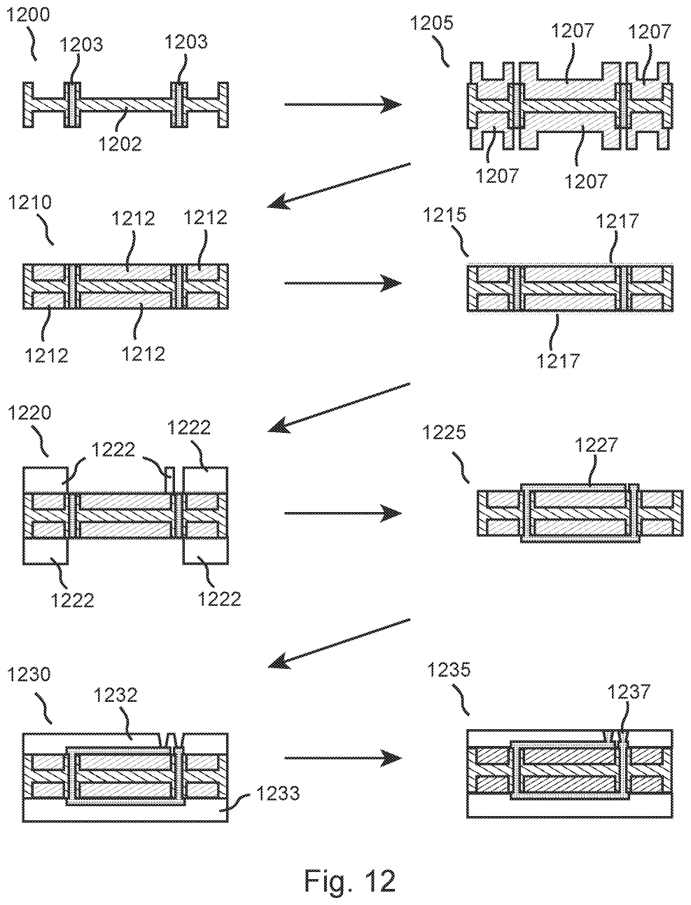

FIG. 12 shows a manufacturing process flow for an inductor structure of FIGS. 7A-7B. Structure 1200 provides a package substrate core 1202 having cavities and through-core vias 1203. The through-core vias 1203 are filled with a conducting material, such as Cu. Structure 1205 was created through the templated cold spray deposition of magnetic material. Structure 1205 has magnetic regions 1207 and magnetic base region (not shown). Mechanical grinding and polishing of magnetic regions 1207 created structure 1210 having magnetic regions 1212. Deposition of a seed layer 1217 created structure 1215. A lithographic mask 1222 shown in structure 1220, was created by depositing a photomask and patterning it lithographically. A copper plating process was used to create conducting feature 1227. Stripping of the lithographic mask yielded structure 1225. Dielectric regions 1232 and 1233 were built up on opposing surfaces of structure 1225 to create structure 1230. Dielectric region 1232 was patterned for micro via creation. Copper metal was deposited into the micro via regions and excess mechanically removed to create structure 1235 having conductive region 1237.

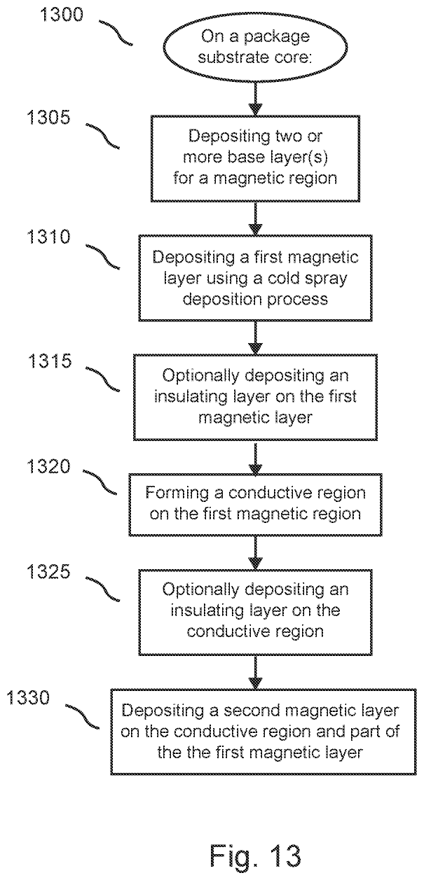

FIG. 13 describes an exemplary method for forming a planar magnetic inductor. In FIG. 13, a package substrate core is used 1300 and a base region is created by depositing two or more layers 1305. As described herein (in for example, FIG. 5 and the accompanying description), the base regions can include a buffer metal layer, an adhesion layer, and optionally a seed layer. A first magnetic region is created using a cold spray deposition process 1310. The magnetic region that is deposited using a cold spray deposition process 1310 can exhibit a morphology such as that shown and described with respect to FIGS. 6A-6B. Optionally, a non-magnetic insulating layer is deposited on the first magnetic region 1315. The non-magnetic insulating layer can have a thickness that is described by equation (1) and the accompanying description herein. A conductive region is then deposited on the first magnetic region 1320. Optionally, depending on the conductor deposition method employed, a seed layer is deposited before the conductor is deposited. In a conductor plating process, for example, the seed layer seeds the formation of the conductive region. If a non-magnetic insulating region is present, the conductive region is deposited on the non-magnetic insulating region. Also optionally, a non-magnetic insulating layer is deposited on the conductive region 1325. The non-magnetic insulating layers are between the magnetic region and the conductive region and are optional. The magnetic region is deposited on the conductive region and over the parts of the first magnetic region not covered by the conductive region 1330. If a non-magnetic insulating layer is present, the magnetic region is deposited on the insulating region.

Further example conductive materials used in conductive regions herein include, for example, Cu or another conductive metal. Example seed layers for conductive materials used in conductive regions described herein include, Ti/Cu, Ta/Cu, TiN/Cu, TaN/Cu, Ti/Ru, Ta/Ru, Ru, and/or Cu. The material combinations, Ti/Cu, Ta/Cu, TiN/Cu, TaN/Cu, Ti/Ru, and Ta/Ru, can be bilayers. In some examples, the seed layer is a combination of different layers. For example, the seed layer can be one or more Ti/Cu or Ta/Cu bi-layers. In further examples, the seed layer 106 is comprised of one or more Ta/Ru or Ti/Ru bilayers. Additional resistive magnetic materials include useful herein include, for example, NiZn Ferrites, Ni Ferrites, Co Ferrites, and CoFeB/SiO₂. Additional examples of less resistive magnetic materials useful herein, include for example, CoFeB, CoFeP, CoFeHfO, CoNiFeS, and CoNiFeVOX (where X is S, P, and/or B). Useful non-magnetic insulating materials include, for example, SiO₂, silicon nitride, silicon oxynitride, and Al₂O₃. Other materials than those described herein are possible.

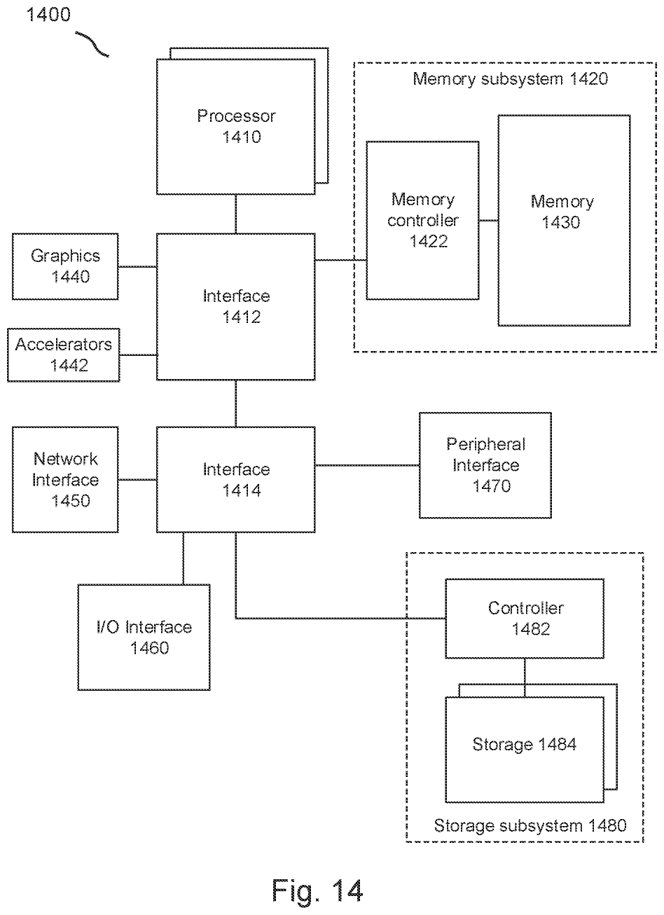

FIG. 14 depicts an example computing system. Semiconductor chips having packages that include magnetic inductors as described herein are part of at least one of the packaged chip components of system 1400, such as for example, the processor 1410. System 1400 includes processor 1410, which provides processing, operation management, and execution of instructions for system 1400. Processor 1410 can include any type of microprocessor, CPU, GPU, processing core, or other processing hardware to provide processing for system 1400, or a combination of processors or processing cores. Processor 1410 controls the overall operation of system 1400, and can be or include, one or more programmable general-purpose or special-purpose microprocessors, DSPs, programmable controllers, ASICs, programmable logic devices (PLDs), or the like, or a combination of such devices.

In one example, system 1400 includes interface 1412 coupled to processor 1410, which can represent a higher speed interface or a high throughput interface for system components needing higher bandwidth connections, such as memory subsystem 1420 or graphics interface components 1440, and/or accelerators 1442. Interface 1412 represents an interface circuit, which can be a standalone component or integrated onto a processor die. Where present, graphics interface 1440 interfaces to graphics components for providing a visual display to a user of system 1400. In one example, the display can include a touchscreen display.

Accelerators 1442 can be a fixed function or programmable offload engine that can be accessed or used by a processor 1410. For example, an accelerator among accelerators 1442 can provide data compression (DC) capability, cryptography services such as public key encryption (PKE), cipher, hash/authentication capabilities, decryption, or other capabilities or services. In some cases, accelerators 1442 can be integrated into a CPU socket (e.g., a connector to a motherboard (or circuit board, printed circuit board, mainboard, system board, or logic board) that includes a CPU and provides an electrical interface with the CPU). For example, accelerators 1442 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 1442 can provide multiple neural networks, CPUs, processor cores, general purpose graphics processing units, or graphics processing units can be made available for use by artificial intelligence (AI) or machine learning (ML) models.

Memory subsystem 1420 represents the main memory of system 1400 and provides storage for code to be executed by processor 1410, or data values to be used in executing a routine. Memory subsystem 1420 can include one or more memory devices 1430 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 1430 stores and hosts, among other things, operating system (OS) to provide a software platform for execution of instructions in system 1400. In one example, memory subsystem 1420 includes memory controller 1422, which is a memory controller to generate and issue commands to memory 1430. The memory controller 1422 could be a physical part of processor 1410 or a physical part of interface 1412. For example, memory controller 1422 can be an integrated memory controller, integrated onto a circuit within processor 1410.

System 1400 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a PCI or PCIe bus, a Hyper Transport or industry standard architecture (ISA) bus, a small computer system interface (SCSI) bus, a USB, or a Firewire bus.

In one example, system 1400 includes interface 1414, which can be coupled to interface 1412. In one example, interface 1414 represents an interface circuit, which can include standalone components and integrated circuitry. In one example, user interface components or peripheral components, or both, couple to interface 1414. Network interface 1450 provides system 1400 the ability to communicate with remote devices (e.g., servers or other computing devices) over one or more networks. Network interface 1450 can include an Ethernet adapter, wireless interconnection components, cellular network interconnection components, USB, or other wired or wireless standards-based or proprietary interfaces. Network interface 1450 can transmit data to a device that is in the same data center or rack or a remote device, which can include sending data stored in memory.

Some examples of network interface 1450 are part of an IPU or DPU, or used by an IPU or DPU. An xPU can refer at least to an IPU, DPU, GPU, GPGPU, or other processing units (e.g., accelerator devices). An IPU or DPU can include a network interface with one or more programmable pipelines or fixed function processors to perform offload of operations that could have been performed by a CPU. The IPU or DPU can include one or more memory devices.

In one example, system 1400 includes one or more input/output (I/O) interface(s) 1460. I/O interface 1460 can include one or more interface components through which a user interacts with system 1400 (e.g., audio, alphanumeric, tactile/touch, or other interfacing). Peripheral interface 1470 can include additional types of hardware interfaces.

In one example, system 1400 includes storage subsystem 1480. Storage subsystem 1480 includes storage device(s) 1484, which can be or include any conventional medium for storing data in a nonvolatile manner, such as one or more magnetic, solid state, and/or optical based disks. Storage 1484 can be generically considered to be a “memory,” although memory 1430 is typically the executing or operating memory to provide instructions to processor 1410. Whereas storage 1484 is nonvolatile, memory 1430 can include volatile memory (e.g., the value or state of the data is indeterminate if power is interrupted to system 1400). In one example, storage subsystem 1480 includes controller 1482 to interface with storage 1484. In one example controller 1482 is a physical part of interface 1414 or processor 1410 or can include circuits or logic in both processor 1410 and interface 1414.

A power source (not depicted) provides power to the components of system 1400. More specifically, power source typically interfaces to one or multiple power supplies in system 1400 to provide power to the components of system 1400. In one example, the power supply includes an AC to DC (alternating current to direct current) adapter to plug into a wall outlet. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

In addition to what is shown, various modifications can be made to what is disclosed without departing from the scope of the invention. The figures and examples described should be understood in an illustrative, and not a restrictive sense.

What is claimed is:

1. A microelectronics package comprising:
a package substrate core;
a magnetic region wherein the magnetic region is on the package substrate core;
a magnetic region base region, wherein magnetic region base region has a chemical composition that is different from the chemical composition of the magnetic region and wherein the magnetic region base region is between the magnetic region and the package substrate core; and
a conductive region, wherein the conductive region forms a channel within the magnetic region and wherein the conductive region has at least one end where no magnetic material is present.

2. The microelectronics package of claim 1 wherein there is a non-magnetic dielectric region between the magnetic region and the conductive region.

3. The microelectronics package of claim 1 wherein there are two or more conductive regions that each form a separate channel within the magnetic region.

4. The microelectronics package of claim 1 wherein the magnetic region is comprised of NiZn Ferrites, Ni Ferrites, Co Ferrites, CoFeB/SiO₂, CoFeB, CoFeP, CoFeHfO, CoNiFeS, or CoNiFeVOx.

5. The microelectronics package of claim 1 wherein the magnetic region base region has a layer that comprises Cu, Au, Ru, Al, or a combination thereof.

6. The microelectronics package of claim 1 wherein the magnetic region base region has a layer that comprises Ti, Ta, SnO, ZnO, or a combination thereof.

7. The microelectronics package of claim 1 wherein the magnetic region base region comprises two or more layers and wherein a first layer has a different chemical composition than a second layer.

8. The microelectronics package of claim 1 wherein the magnetic region is comprised of a material that is a homogeneous magnetic material.

9. The microelectronics package of claim 1 wherein the magnetic region is at least partially recessed into the package substrate core.

10. The microelectronics package of claim 9 wherein the magnetic region comprises a first and a second magnetic region and wherein the first magnetic region has a different chemical composition than the second magnetic region.

11. A microelectronics package comprising:
a package substrate core;
a first magnetic region, wherein the first magnetic region is recessed into the package substrate core on a first side of the package substrate core and wherein the first magnetic region is a homogeneous magnetic material; and
a conductive region, wherein the conductive region comprises at least two through-core vias and wherein the conductive region at least partially encircles a portion of the package substrate core comprising the first magnetic region.

12. The microelectronics package of claim 11 additionally comprising a second and third magnetic regions that are recessed into the package substrate core in an area that is adjacent to a region of the package substrate core that comprises the first magnetic region and that is partially encircled by the conductive region.

13. The microelectronics package of claim 11 additionally comprising a base region that is between the first magnetic region and the package substrate core and the base region has a different chemical composition than the first magnetic region.

14. The microelectronics package of claim 11, wherein the base region has a layer that comprises Cu, Au, Ru, Al, or a combination thereof.

15. A semiconductor assembly comprising:
at least one semiconductor chip; and
a semiconductor chip package substrate wherein the at least one semiconductor chip is electrically coupled to the semiconductor chip package substrate and wherein the semiconductor chip package substrate comprises:
a package substrate core wherein the package substrate core comprises an inductor and the inductor comprises:
a magnetic region wherein the magnetic region is located within the package substrate,
a base region, wherein the base region is between the magnetic region and the package substrate core; and
a conductive region, wherein the conductive region forms a channel within the magnetic region and wherein the conductive region has at least one end where no magnetic material is present.

16. The semiconductor assembly of claim 15 wherein the semiconductor chip package substrate additionally includes layers that have conducting regions.

17. The semiconductor assembly of claim 15 wherein the base region has a layer that comprises Cu, Au, Ru, Al, or a combination thereof.

18. A method of manufacturing a semiconductor chip package comprising:
depositing a base region for a magnetic region on a packaging substrate core,
forming a first magnetic layer using a cold spray deposition process,
forming a conductive region on part of the first magnetic layer,
forming a second magnetic layer on the conductive region and part of the first magnetic layer using a cold spray deposition process.

19. The method of claim 18 wherein the base region comprises two layers and depositing a base region includes depositing an adhesion layer and depositing a buffer metal layer.

20. The method of claim 18 wherein the base region has a layer that comprises Ti, Ta, SnO, ZnO, or a combination thereof.
